(19) United States
(12) Patent Application Publication
(10) Pub. No.: US 2026/0310468 A1
(43) Pub. Date: Oct. 8, 2026

(54) MEMORY PERFORMING TRAINING OPERATION, MEMORY SYSTEM, AND OPERATION METHOD OF THE MEMORY SYSTEM

(71) Applicant: SK hynix Inc., Gyeonggi-do (KR)

(72) Inventors: Kyu Young KIM, Gyeonggi-do (KR); Min O KIM, Gyeonggi-do (KR); Jae Yeol KANG, Gyeonggi-do (KR); Han Byeol KWON, Gyeonggi-do (KR); Jung Taek YOU, Gyeonggi-do (KR); Hyeong Soo JEONG, Gyeonggi-do (KR)

(21) Appl. No.: 19/387,644

(22) Filed: Nov. 13, 2025

(30) Foreign Application Priority Data
Apr. 3, 2025 (KR) 10-2025-0043517
Jul. 31, 2025 (KR) 10-2025-0105216

(51) Int. Cl. G06F 9/4401; G11C 7/22; H03K 3/037

(52) U.S. Cl. CPC G06F 9/4401; G11C 7/22; H03K 3/037

(57) ABSTRACT

A memory is provided. The memory includes a first detector configured to consecutively detect a logic level of a chip select signal in synchronization with a first clock, a second detector configured to consecutively detect a logic level of the chip select signal in synchronization with a second clock having a phase opposite to a phase of the first clock, and a pass-fail determination circuit configured to determine a training operation to be a pass when the logic level consecutively detected by the first detector and the logic level consecutively detected by the second detector are different from each other.

### CROSS-REFERENCE TO RELATED APPLICATIONS

This application claims priority under 35 U.S.C. §119(a) to Korean Patent Application Nos. 10-2025-0043517 and 10-2025-0105216, filed on APR. 3 and JUL. 31, 2025, respectively, the entire contents of which are incorporated herein by reference.

### BACKGROUND

### Technical Field

Embodiments relate to memory, and more particularly, to a memory performing a training operation.

### Related Art

In order for memory to operate normally, a training operation related to the input and output of various signals needs to be completed. The training operation is usually performed after the start of an initial operation of the memory. The input and output operations of signals can be stably performed during a subsequent operation of the memory only when the training operation is performed correctly.

### SUMMARY

In an embodiment, a memory may include a first detector configured to consecutively detect a logic level of a chip select signal in synchronization with a first clock, a second detector configured to consecutively detect a logic level of the chip select signal in synchronization with a second clock having a phase opposite to a phase of the first clock, and a pass and fail (pass/fail) determination circuit configured to determine a training operation to be a pass when the logic level consecutively detected by the first detector and the logic level consecutively detected by the second detector are different from each other.

In an embodiment, an operating method of a memory system may include transmitting a clock from a memory controller to a memory, setting the memory in a first mode, toggling a chip select signal that is transmitted from the memory controller to the memory, detecting, by the memory, a logic level of the chip select signal N times at an even rising edge of the clock, where N is an integer equal to or greater than 2, detecting, by the memory, a logic level of the chip select signal N times at an odd rising edge of the clock, and determining, by the memory, training in the first mode to be a pass when the logic level of the chip select signal is detected as a high level N times at the even rising edge and the logic level of the chip select signal is detected as a low level N times at the odd rising edge.

In an embodiment, a memory system may include a memory controller configured to transmit a clock and a chip select signal and a memory configured to receive the clock and the chip select signal and configured to transmit results of training to the memory controller by detecting a logic level of the chip select signal N times at an even rising edge of the clock and detecting a logic level of the chip select signal N times at an odd rising edge of the clock, where N is an integer equal to or greater than 2.

### BRIEF DESCRIPTION OF THE DRAWINGS

FIG. 1 is a construction diagram of memory 100 according to an embodiment of the present disclosure.

FIG. 2 is a construction diagram according to an embodiment of a first detector 110 illustrated in FIG. 1.

FIG. 3 is a construction diagram according to an embodiment of a pass-fail determination circuit 130 illustrated in FIG. 1.

FIGS. 4 and 5 are timing diagrams illustrating a chip select training operation of the memory 100 illustrated in FIGS. 1 to 3.

FIG. 6 is a construction diagram according to another embodiment of a pass-fail determination circuit 130 illustrated in FIG. 1.

FIG. 7 is a timing diagram illustrating a fail zone of a chip select training operation of the memory 100.

FIG. 8 is a construction diagram of a memory system 800 according to an embodiment of the present disclosure.

### DETAILED DESCRIPTION

Hereinafter, embodiments according to the technical spirit of the present disclosure are described with reference to the accompanying drawings.

Embodiments of the present disclosure may provide a technology in which a training operation of memory is performed stably.

In accordance with embodiments of the present disclosure, technology may be provided in which a training operation of memory is performed stably.

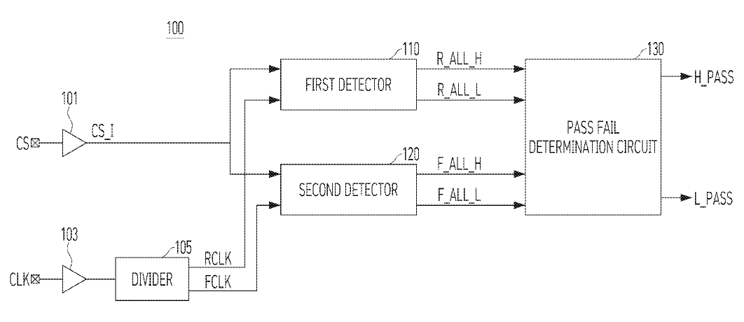

FIG. 1 is a construction diagram of memory 100 according to an embodiment of the present disclosure. FIG. 1 illustrates components related to a chip select training (CST) operation in the memory 100.

Referring to FIG. 1, the memory 100 may include a chip select reception circuit 101, a clock reception circuit 103, a divider 105, a first detector 110, a second detector 120, and a pass and fail (pass/fail) determination circuit 130.

The chip select reception circuit 101 may receive a chip select signal CS_I of a chip select terminal CS. The chip select reception circuit 101 may determine a logic level of the chip select signal CS_I by determining whether the voltage level of the chip select terminal CS is greater than or less than the voltage level of a chip select reference voltage VREFCS.

The clock reception circuit 103 may receive a clock CLK of a clock terminal CLK. The divider 105 may generate a first clock RCLK and a second clock FCLK by dividing the clock CLK into two. The frequency of each of the first clock RCLK and the second clock FCLK is 1/2 (half) the frequency of the clock CLK. A rising edge of the first clock RCLK may be aligned with an even rising edge of the clock CLK. A rising edge of the second clock FCLK may be aligned with an odd rising edge of the clock CLK. That is, the first clock RCLK and the second clock FCLK may have opposite phases.

The first detector 110 may consecutively detect (for example, repeatedly sample and check a signal's logic level over several clock cycles) the level of the chip select signal CS_I in synchronization with the first clock RCLK. The first detector 110 may consecutively detect the logic level of the chip select signal CS_I at a rising edge of the first clock RCLK, and may output the detection results R_ALL_H and R_ALL_L. The first all-high signal R_ALL_H may be a signal indicating that the logic level of the chip select signal CS_I has been consecutively detected as a high level N times (N is an integer equal to or greater than 2) at the rising edge of the first clock RCLK. The first all-low signal R_ALL_L may be a signal indicating that the logic level of the chip select signal CS_I has been consecutively detected as a low level N times at the rising edge of the first clock RCLK.

The second detector 120 may consecutively detect the level of the chip select signal CS_I in synchronization with the second clock FCLK. The second detector 120 may consecutively detect a logic level of the chip select signal CS_I at a rising edge of the second clock FCLK, and may output the detection results F_ALL_H and F_ALL_L. The second all-high signal F_ALL_H may be a signal indicating that the logic level of the chip select signal CS_I has been consecutively detected as a high level N times at the rising edge of the second clock FCLK. The second all-low signal F_ALL_L may be a signal indicating that the logic level of the chip select signal CS_I has been consecutively detected as a low level N times at the rising edge of the second clock FCLK.

The pass/fail determination circuit 130 may determine a pass or fail of a chip select training (CST) operation based on the detection results R_ALL_H and R_ALL_L of the first detector 110 and the detection results F_ALL_H and F_ALL_L of the second detector 120. The activation of both a high pass signal H_PASS and low pass signal L_PASS of the pass/fail determination circuit 130 may indicate a pass of a CST operation.

The CST operation is a training operation of activating the chip select signal CS_I that is transmitted from a memory controller to the memory 100 N times during 2N cycles of the clock CLK, that is, N cycles on the basis of the first clock RCLK and the second clock FCLK, and checking whether a logic level of the chip select signal CS_I is well recognized. Accordingly, a case in which a high level of the chip select signal CS_I is consecutively detected N times by the first detector 110 and a low level of the chip select signal CS_I is consecutively detected N times by the second detector 120 may be determined to be a pass. Alternatively, a case in which a low level of the chip select signal CS_I is consecutively detected N times by the first detector 110 and a high level of the chip select signal CS_I is consecutively detected N times by the second detector 120 may be determined to be a pass.

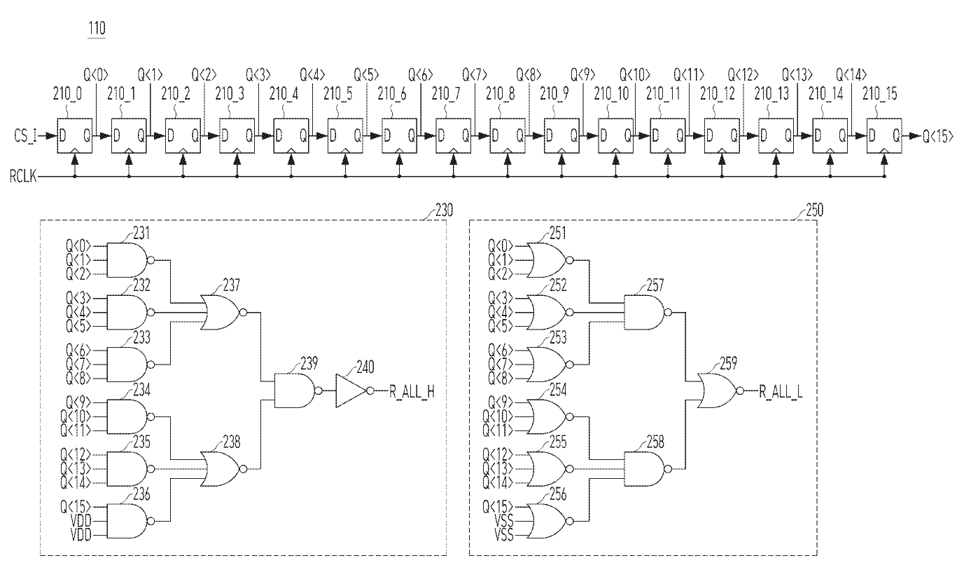

FIG. 2 is a construction diagram according to an embodiment of the first detector 110 illustrated in FIG. 1.

Referring to FIG. 2, the first detector 110 may include D flip-flops 210_0 to 210_15, an all-high signal generation circuit 230, and an all-low signal generation circuit 250.

The D flip-flops 210_0 to 210_15 are connected in series, and may operate in synchronization with the first clock RCLK. The chip select signal CS_I may be input to the input terminal D of the D flip-flop 210_0 at the first stage, and the signal of the output terminal Q of the D flip-flop at a previous stage may be input to the input terminal D of each of the remaining D flip-flops 210_1 to 210_15. Each of the D flip-flops 210_1 to 210_15 may receive and store the signal of the input terminal D at a rising edge of the first clock RCLK, and may output the stored signal to the output terminal Q.

The all-high signal generation circuit 230 may activate the first all-high signal R_ALL_H to a high level when all of the output signals Q<0> to Q<15> of the D flip-flops 210_0 to 210_15 have a high level, that is, when the logic level of the chip select signal CS_I is consecutively detected as a high level N times (in this case, 16 times) at a rising edge of the first clock RCLK. The all-high signal generation circuit 230 may include NAND gates 231 to 236 and 239, NOR gates 237 and 238, and an inverter 240.

The all-low signal generation circuit 250 may activate the first all-low signal R_ALL_L to a high level when all of the output signals Q<0> to Q<15> of the D flip-flops 210_0 to 210_15 have a low level, that is, when the logic level of the chip select signal CS_I is consecutively detected as a low level N times (hereinafter denoted as N=16) at a rising edge of the first clock RCLK. The all-low signal generation circuit 250 may include NOR gates 251 to 256 and 259 and NAND gates 257 and 258.

The second detector 120 may be constructed identically with the first detector 110. The first detector 110 of FIG. 2 may become the second detector 120 by replacing the first clock RCLK with the second clock FCLK and replacing the output signals R_ALL_H and R_ALL_L with the signals F_ALL_H and F_ALL_L.

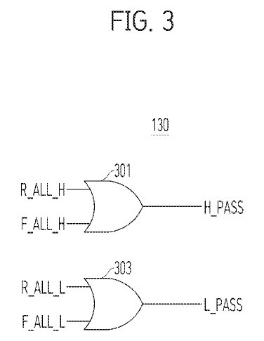

FIG. 3 is a construction diagram according to an embodiment of the pass/fail determination circuit 130 illustrated in FIG. 1.

Referring to FIG. 3, the pass/fail determination circuit 130 may include OR gates 301 and 303.

The OR gate 301 may activate the high pass signal H_PASS when the first all-high signal R_ALL_H or the second all-high signal F_ALL_H is activated. The OR gate 303 may activate the low pass signal L_PASS when the first all-low signal R_ALL_L or the second all-low signal F_ALL_L is activated.

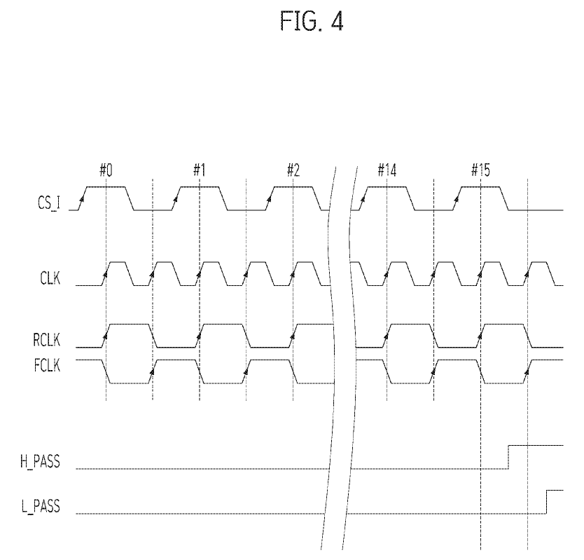

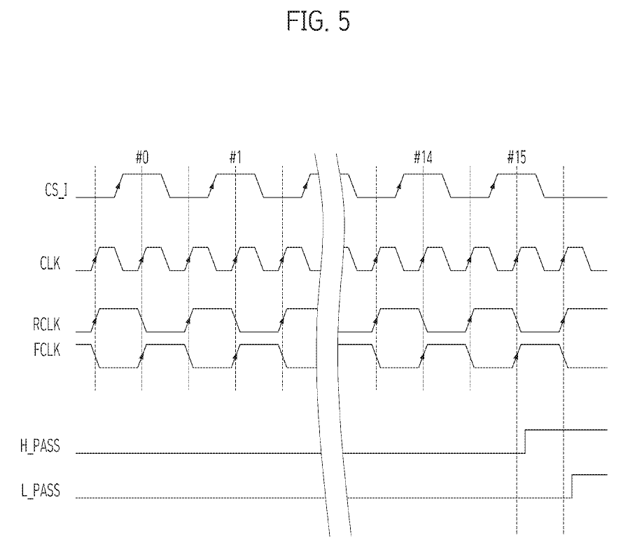

FIGS. 4 and 5 are timing diagrams illustrating a CST operation of the memory 100 illustrated in FIGS. 1 to 3.

FIG. 4 illustrates a case in which a logic level of the chip select signal CS_I is detected as a high level 16 times (at each of timing 0 to 15) at a rising edge of the first clock RCLK and a logic level of the chip select signal CS_I is detected as a low level 16 times at a rising edge of the second clock FCLK. In this case, the CST operation may be determined to be a pass because the high pass signal H_PASS and the low pass signal L_PASS are activated. When the CST operation is determined to be not a pass, the CST operation may be performed again by adjusting timing of the chip select signal CS_I quickly or slowly (for example, either quickening or slowing the signal's timing until it correctly synchronizes with the clock signals and passes the test).

FIG. 5 illustrates a case in which a logic level of the chip select signal CS_I is detected as a low level 16 times at a rising edge of the first clock RCLK and a logic level of the chip select signal CS_I is detected as a high level 16 times at a rising edge of the second clock FCLK. In this case, the CST operation may be determined to be a pass because the high pass signal H_PASS and the low pass signal L_PASS are activated.

In a training operation, such as that illustrated in FIGS. 4 and 5, when a logic level of the chip select signal CS_I is detected as a high level 16 times at a rising edge of the first clock RCLK and a logic level of the chip select signal CS_I is detected as a low level 16 times at a rising edge of the second clock FCLK, a CST operation is determined to be a pass. Even in an opposite case, a CST operation is determined to be a pass. That is, when any one of combinations of the first clock RCLK and the second clock FCLK is satisfied, a CST operation is determined to be a pass. Accordingly, the fail zone of the CST operation is very narrow when a rising edge of the first clock RCLK or the second clock FCLK and a rising edge or falling edge of the chip select signal CS_I overlaps. When the fail zone is narrow as described above, it may be difficult to obtain reliable training results because it is difficult to find an optimal timing point of the chip select signal CS_I.

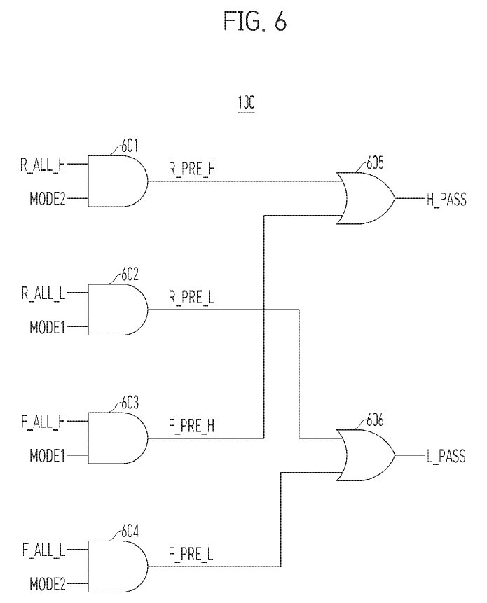

FIG. 6 is a construction diagram according to another embodiment of the pass/fail determination circuit 130 illustrated in FIG. 1.

The pass/fail determination circuit 130 of FIG. 6 can widen the fail zone of a training operation by introducing a first mode and a second mode in the pass/fail determination circuit 130 of FIG. 3. That is, the pass/fail determination circuit 130 of FIG. 6 can improve the reliability of a CST operation.

Referring to FIG. 6, the pass/fail determination circuit 130 may include a first preliminary high pass signal generation unit 601, a first preliminary low pass signal generation unit 602, a second preliminary high pass signal generation unit 603, a second preliminary low pass signal generation unit 604, a high pass signal generation unit 605, and a low pass signal generation unit 606.

A first mode signal MODE1 may be a signal that is activated to a low level when the first mode is set. A second mode signal MODE2 may be a signal that is activated to a low level when the second mode is set. The first mode may be a mode in which a CST operation is determined to be a pass only when a logic level of the chip select signal CS_I is detected as a high level at a rising edge of the first clock RCLK and a logic level of the chip select signal CS_I is detected as a low level at a rising edge of the second clock FCLK, that is, only when the first all-high signal R_ALL_H and the second all-low signal F_ALL_L are activated. The second mode may be a mode in which a CST operation is determined to be a pass only when a logic level of the chip select signal CS_I is detected as a high level at a rising edge of the second clock FCLK and a logic level of the chip select signal CS_I is detected as a low level at a rising edge of the first clock RCLK, that is, only when the first all-low signal R_ALL_L and the second all-high signal F_ALL_H are activated.

The first preliminary high pass signal generation unit 601 may activate a first preliminary high pass signal R_PRE_H in response to the activation of the first all-high signal R_ALL_H, but may fix the first preliminary high pass signal R_PRE_H in a deactivation state when the second mode is set. The first preliminary high pass signal generation unit 601 may include an AND gate that outputs the first preliminary high pass signal R_PRE_H based on the first all-high signal R_ALL_H and the second mode signal MODE2.

The first preliminary low pass signal generation unit 602 may activate a first preliminary low pass signal R_PRE_L in response to the activation of the first all-low signal R_ALL_L, but may fix the first preliminary low pass signal R_PRE_L in the deactivation state when the first mode is set. The first preliminary low pass signal generation unit 602 may include an AND gate that outputs the first preliminary low pass signal R_PRE_L based on (for example, the received) the first all-low signal R_ALL_L and the first mode signal MODE1.

The second preliminary high pass signal generation unit 603 may activate a second preliminary high pass signal F_PRE_H in response to the activation of the second all-high signal F_ALL_H, but may fix the second preliminary high pass signal F_PRE_H in the deactivation state when the first mode is set. The second preliminary high pass signal generation unit 603 may include an AND gate that outputs the second preliminary high pass signal F_PRE_H based on the second all-high signal F_ALL_H and the first mode signal MODE1.

The second preliminary low pass signal generation unit 604 may activate a second preliminary low pass signal F_PRE_L in response to the activation of the second all-low signal F_ALL_L, but may fix the second preliminary low pass signal F_PRE_L in the deactivation state when the second mode is set. The second preliminary low pass signal generation unit 604 may include an AND gate that outputs the second preliminary low pass signal F_PRE_L based on the second all-low signal F_ALL_L and the second mode signal MODE2.

The high pass signal generation unit 605 may activate the high pass signal H_PASS when the first preliminary high pass signal R_PRE_H or the second preliminary high pass signal F_PRE_H is activated. The high pass signal generation unit 605 may include an OR gate that outputs the high pass signal H_PASS based on the first preliminary high pass signal R_PRE_H and the second preliminary high pass signal F_PRE_H.

The low pass signal generation unit 606 may activate the low pass signal L_PASS when the first preliminary low pass signal R_PRE_L or the second preliminary low pass signal F_PRE_L is activated. The low pass signal generation unit 606 may include an OR gate that outputs the low pass signal L_PASS based on the first preliminary low pass signal R_PRE_L and the second preliminary low pass signal F_PRE_L.

When the first mode is set, the pass/fail determination circuit 130 of FIG. 6 may determine a CST operation to be a pass when the chip select signal CS_I is input as illustrated in FIG. 4, but may determine a CST operation to be a fail when the chip select signal CS_I is input as illustrated in FIG. 5.

When the second mode is set, the pass/fail determination circuit 130 of FIG. 6 may determine a CST operation to be a pass when the chip select signal CS_I is input as illustrated in FIG. 5, but may determine a CST operation to be a fail when the chip select signal CS_I is input as illustrated in FIG. 4.

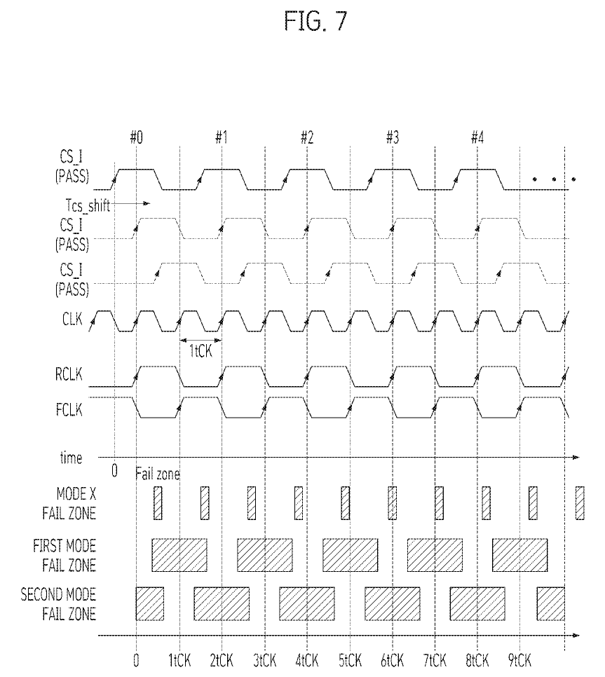

FIG. 7 is a timing diagram illustrating a fail zone of a CST operation of the memory 100. When a rising edge of the chip select signal CS_I is present within the fail zone, the CST operation may be determined to be a fail.

FIG. 7 illustrates cases in which a CST operation is determined to be a pass and a fail based on timing of the chip select signal CS_I. In FIG. 7, Tcs_shift indicates a shifted value of the chip select signal CS_I.

It may be seen that when a mode is not set (Mode X Fail Zone), a fail zone is very narrow if the pass/fail determination circuit 130 is constructed as illustrated in FIG. 3. In this case, the fail zone is very narrow (for example, relative to a clock cycle 1tCK) when a rising edge of the first clock RCLK or the second clock FCLK and a rising edge or falling edge of the chip select signal CS_I overlap. When the fail zone is narrowly formed as described above, a memory controller may easily determine a CST operation to be a pass. As a result, it may be difficult to secure the reliability of the CST operation.

It may be seen that the fail zone is widely formed when the first mode is set (First Mode Fail Zone) and when the second mode is set (Second Mode Fail Zone). When the fail zone is widely formed, a definite fail zone is secured. Accordingly, a pass determination of a CST operation may become stricter. As a result, it is possible to secure the reliability of a training operation.

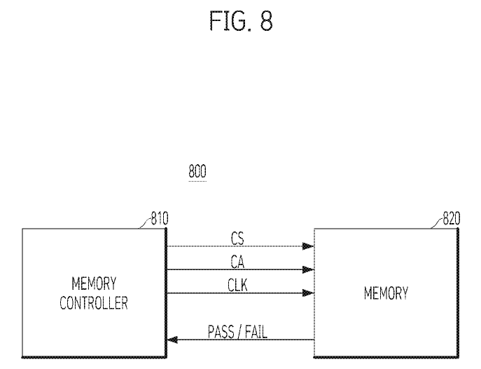

FIG. 8 is a construction diagram of a memory system 800 according to an embodiment of the present disclosure.

Referring to FIG. 8, the memory system 800 may include a memory controller 810 and a memory 820. The memory controller 810 may control the memory 820 by transmitting the chip select signal CS, a command address CA, and the clock CLK to the memory 820. The memory 820 may perform a CST operation by control of the chip select signal CS and the command address CA. The first mode and the second mode may be set.

As described with reference to FIGS. 1 to 7, the memory 820 may perform a CST operation under the control of the memory controller 810, and may transmit, to the memory controller 810, the results PASS/FAIL of the CST operation. The results PASS/FAIL may include only information indicating whether the CST operation is determined to be a pass or a fail, and may include information indicative of the high pass signal H_PASS and the low pass signal L_PASS. That is, information indicating whether the CST operation is a high pass or a low pass may be included in the results PASS/FAIL.

The technical spirit of the present disclosure has been described in detail based on the embodiments, but it is to be noted that the embodiments are provided for the descriptions thereof and not for restriction thereof. Furthermore, an expert in the field to which the present disclosure pertains will understand that various embodiments are possible without departing from the technical spirit of the present disclosure.

What is claimed is:

1. A memory comprising:
a first detector configured to consecutively detect a logic level of a chip select signal in synchronization with a first clock;
a second detector configured to consecutively detect a logic level of the chip select signal in synchronization with a second clock having a phase opposite to a phase of the first clock; and
a pass and fail (pass/fail) determination circuit configured to determine a training operation to be a pass when the logic level consecutively detected by the first detector and the logic level consecutively detected by the second detector are different from each other.

2. The memory of claim 1, wherein, when a first mode is set, the pass/fail determination circuit is configured to determine the training operation to be a pass when high levels are consecutively detected by the first detector and low levels are consecutively detected by the second detector.

3. The memory of claim 2, wherein, when a second mode is set, the pass/fail determination circuit is configured to determine the training operation to be a pass when low levels are consecutively detected by the first detector and high levels are consecutively detected by the second detector.

4. The memory of claim 1, further comprising:
a clock reception circuit configured to receive a clock; and
a divider configured to generate the first clock and the second clock by dividing the clock.

5. The memory of claim 4, further comprising a chip select reception circuit configured to receive the chip select signal.

6. The memory of claim 1, wherein the first detector comprises:
a plurality of first D flip-flops connected in series and configured to operate in synchronization with the first clock, wherein the chip select signal is input to a first D flip-flop at a first stage, among the plurality of first D flip-flops;
a first all-high signal generation circuit configured to activate a first all-high signal when all of output signals of the plurality of first D flip-flops have a high level; and
a first all-low signal generation circuit configured to activate a first all-low signal when all of the output signals of the plurality of first D flip-flops have a low level.

7. The memory of claim 6, wherein the second detector comprises:
a plurality of second D flip-flops connected in series and configured to operate in synchronization with the second clock, wherein the chip select signal is input to a second D flip-flop at a first stage, among the plurality of second D flip-flops;
a second all-high signal generation circuit configured to activate a second all-high signal when all of output signals of the plurality of second D flip-flops have a high level; and
a second all-low signal generation circuit configured to activate a second all-low signal when all of the output signals of the plurality of second D flip-flops have a low level.

8. The memory of claim 7, wherein the pass/fail determination circuit is further configured to:
determine the training operation to be a pass when the first all-high signal and the second all-low signal are activated when a first mode is set, and
determine the training operation to be a pass when the first all-low signal and the second all-high signal are activated when a second mode is set.

9. The memory of claim 7, wherein the pass/fail determination circuit comprises:
a first preliminary high pass signal generation unit configured to activate a first preliminary high pass signal in response to the activation of the first all-high signal and configured to fix the first preliminary high pass signal in a deactivation state when a second mode is set;
a first preliminary low pass signal generation unit configured to activate a first preliminary low pass signal in response to the activation of the first all-low signal and configured to fix the first preliminary low pass signal in the deactivation state when a first mode is set;
a second preliminary high pass signal generation unit configured to activate a second preliminary high pass signal in response to the activation of the second all-high signal and configured to fix the second preliminary high pass signal in the deactivation state when the first mode is set;
a second preliminary low pass signal generation unit configured to activate a second preliminary low pass signal in response to the activation of the second all-low signal and configured to fix the second preliminary low pass signal in the deactivation state when the second mode is set;
a high pass signal generation unit configured to activate a high pass signal when one or more of the first preliminary high pass signal and the second preliminary high pass signal are activated; and
a low pass signal generation unit configured to activate a low pass signal when one or more of the first preliminary low pass signal and the second preliminary low pass signal are activated.

10. The memory of claim 7, wherein:
a number of the plurality of first D flip-flops is 16, and
a number of the plurality of second D flip-flops is 16.

11. An operating method of a memory system, comprising:
transmitting a clock from a memory controller to a memory;
setting the memory in a first mode;
toggling a chip select signal that is transmitted from the memory controller to the memory;
detecting, by the memory, a logic level of the chip select signal N times at an even rising edge of the clock, where N is an integer greater than or equal to 2;
detecting, by the memory, a logic level of the chip select signal N times at an odd rising edge of the clock; and
determining, by the memory, training in the first mode to be a pass when the logic level of the chip select signal is detected as a high level N times at the even rising edge and the logic level of the chip select signal is detected as a low level N times at the odd rising edge.

12. The operating method of claim 11, further comprising:
setting the memory in a second mode;
toggling the chip select signal;
detecting, by the memory, a logic level of the chip select signal N times at the even rising edge;
detecting, by the memory, a logic level of the chip select signal N times at the odd rising edge; and
determining, by the memory, training in the second mode to be a pass when the logic level of the chip select signal is detected as a high level N times at the odd rising edge and the logic level of the chip select signal is detected as a low level N times at the even rising edge.

13. The operating method of claim 12, wherein N is 16.

14. A memory system comprising:
a memory controller configured to transmit a clock and a chip select signal; and
a memory configured to receive the clock and the chip select signal and configured to transmit results of training to the memory controller by detecting a logic level of the chip select signal N times at an even rising edge of the clock and detecting a logic level of the chip select signal N times at an odd rising edge of the clock, where N is an integer greater than or equal to 2.

15. The memory system of claim 14, wherein, when the memory is set in a first mode, the memory is configured to determine the results of the training to be a pass when the logic level of the chip select signal is consecutively detected as a high level at the even rising edge of the clock and the logic level of the chip select signal is consecutively detected as a low level at the odd rising edge of the clock.

16. The memory system of claim 14, wherein, when the memory is set in a second mode, the memory is configured to determine the results of the training to be a pass when the logic level of the chip select signal is consecutively detected as a low level at the even rising edge of the clock and the logic level of the chip select signal is consecutively detected as a high level at the odd rising edge of the clock.

17. The memory of claim 1, wherein the training operation includes activating the chip select signal.

18. The memory system of claim 14, wherein the training includes activating the chip select signal.
